(19) United States
(12) Patent Application Publication
(10) Pub. No.: US 2001/0039131 A1
(43) Pub. Date: Nov. 8, 2001

(54) Electrical connection box

(75) Inventors: Masakazu Murakami, Hikone-shi (JP); Naomi Noguchi, Kameyama-shi (JP); Keiji Edamura, Kameyama-shi (JP)

Correspondence Address: FRISHAUF, HOLTZ, GOODMAN &, LANGER & CHICK, PC, 767 THIRD AVENUE, 25TH AVE, NEW YORK, NY, 10017-2023, US

(73) Assignee: THE FURUKAWA ELECTRIC CO., LTD., Tokyo (JP)

(21) Appl. No.: 09/905,768

(22) Filed: Jul. 13, 2001

Related U.S. Application Data
(62) Division of application No. 09/393,745, filed on Sep. 10, 1999.

(30) Foreign Application Priority Data
Sep. 14, 1998 (JP) 10-259805
Sep. 30, 1998 (JP) 10-278659

(51) Int. Cl. H05K 1/00

(52) U.S. Cl. 439/76.2

(57) ABSTRACT

An electrical connection box for carrying electrical components comprises first and second casings capable of being combined with each other and an electrically insulating wiring board located between the casings and having a wire laid in a desired shape thereon. The wiring board has a wiring path in a desired shape and a holding portion for holding the leader of the wire laid in the wiring path. The wiring board, first casing, and/or second casing is formed having a holding portion for holding the trailer of the wire and preventing interference between the wire trailer and the first or second casing that adjoins the wire trailer.

### BACKGROUND OF THE INVENTION

1. Field of the Invention

The present invention relates to an electrical connection box, and more specifically, to an electrical connection box mounted in an automobile or the like and loaded with electrical components.

2. Description of the Related Art

As vehicles, e.g., automobiles, are expected to meet increasing market requirements for comfortable riding, they tend to require use of increased built-in electric devices, such as an audio system, navigation system, TV set, power antenna, air conditioner, rear window heater, seat heater, power seat, suspension hardness control device, etc.

The built-in electric devices are supplied with electric power from a battery in an engine room through an electrical connection box near the battery and a wire harness. In some cases, excessive current may flow in the electrical connection box if the vehicle body and the wire harness or the like are shorted or if a load such as a motor goes wrong from any cause. The electrical connection box is mounted with electrical components, such as fuses to cope with such trouble and relays that control power supply to the built-in electric devices in association with various operating switches.

As is schematically shown in the exploded perspective view of FIG. 9, the electrical connection box comprises lower and upper casings 1 and 2 capable of being combined with each other, an electrically insulating wiring board 3 located between the casings 1 and 2 and having a wire W laid in a desired shape (shown only partially in FIG. 9) thereon, pressure-welded terminals 3t for electrical connection between wire W and electrical components and connection between wires, and the like. The lower and upper casings 1 and 2 are fitted with electrical components, such as relays 7, fuses 8, external connecting terminals 2a to be connected to the body-side wire harness, etc., which are located individually in given positions.

As is partially shown in FIG. 11, the wiring board 3 is formed with a large number of laying grooves 3s, which are a little wider than the wire W and extend lengthwise and crosswise so that the wire W can be laid in a desired shape therein. A notch 3k for supporting a trailer Ws of the laid wire W is formed in a given position on the outer edge of the wiring board 3. The notch 3k has a width substantially equal to the diameter of the wire W. Further, the wire W is fitted in the laying grooves 3s to be laid in a predetermined path, and the wire trailer Ws is cut just outside the notch 3k.

In general, the wire laying operation is carried out by means of an automatic laying apparatus. More specifically, the leader of the wire W is inserted into a given position in one of the laying grooves 3s by means of the laying apparatus (not shown). Subsequently, the wire W is continuously laid with one stroke along the predetermined path of the laying grooves 3s, led out through the notch 3k shown in FIG. 11, and cut near the notch 3k by means of a cutter (not shown) that is attached to a wire supply nozzle portion of the laying apparatus. Thereafter, the continuously laid wire W is cut at given spots to be divided for each desired circuit. Further, the pressure-welded terminals 3t are driven in given positions on the wire W so that they can conduct to the wire W, electrical components, and wire harness connectors for the individual circuits.

After the laying operation described above is finished, a busbar 4c is attached to one side face (lower surface in FIG. 9) of the wiring board 3, and the lower casing 1 is attached to the busbar 4c. Further, the upper casing 2 and an insulating plate 5, which is fitted with busbars 4a and 4b, are mounted on the other side face (upper surface in FIG. 9) of the wiring board 3, and an electronic control unit 6 is attached. Furthermore, the electrical components, such as the relays 7, fuses 8, etc., are attached to the resulting structure, whereupon the electrical connection box is completed.

In actual laying operation, a wire is generally cut in its trailer position by means of a cutter that is located near a wire supply head. If the wire is cut in the trailer Ws position, that portion of the wire which extends from the wire supply head to the cut end portion is left outside the head. For example, a wire portion with a length of about 5 mm is left outside the head. In starting another cycle of laying operation, a push pin of the automatic laying apparatus is held against the projecting end portion (leader) of the wire and made to push the end portion into a predetermined wiring starting position in a laying groove.

When the trailer of the wire is cut, however, the wire end portion sometimes may be left bent because the wire is sheared by means of the cutter. Since the wire is rolled when it is set in the laying apparatus, moreover, the wire portion that projects from the head remains curly, so that the wire end portion may be left bent in some cases.

In many cases, it is hard to push the curly wire leader suitably into the groove portion of the wiring board by means of the push pin in a subsequent cycle of laying operation. More specifically, as shown in FIGS. 10, the end Ws of the wire W may unduly project from or be lifted out of the laying grooves 3s that extend along the predetermined path in the wiring board 3. If the wire leader is in this state, it interferes with a busbar for high-current conduction. In consequence, a conductor that is exposed through the wire leader may possibly touch the busbar. If the use of the electrical connection box is prolonged, moreover, the wire leader and the busbar may inevitably be caused to rub against each other by the vehicle's vibration, so that an insulator-coated portion of the leader may break, possibly causing a short circuit.

Accordingly, it is necessary to see if the wire leader projects from or is lifted out of the laying grooves every time the laying operation is finished. If such projection or lifting is detected, an extra operation is needed to push the wire leader into the laying grooves. Thus, the conventional laying operation often requires additional checking and wiring operations.

In the case of a laying groove shown in FIGS. 1 and 2 of Jpn. Pat. Appln. KOKAI Publication No. 9-65547, in particular, its portion that corresponds to the leader of a wire is substantially as wide as the wire and bent sharply. If the wire leader is curly, as mentioned before, in this case, it is hard to push it fully into the laying groove by means of the push pin of the automatic laying apparatus only.

If the wire W is cut by means of the cutter to finish the laying operation for the wiring board 3, it projects a little (e.g., about 2 mm) from the notch 3k, as shown in FIGS. 9 and 11. If the wiring board 3 is attached to the lower casing 1 with the wire W projecting from the outer edge of the board 3, the wire trailer Ws and the peripheral wall of the casing 1 interfere with each other, as shown in FIG. 12. Thereupon, the wiring board 3 and the lower casing 1 cannot be coupled with ease. Preventing this interference requires an extra operation to cut the wire trailer Ws again. If the projection of the wire W is not very long (e.g., shorter than 2 mm), on the other hand, the wire trailer Ws is pushed up by the peripheral edge portion of the lower casing 1 as the wiring board 3 is attached to the casing 1, so that the wire W may possibly slip out of the notch 3k. If a vehicle or like is loaded with the electrical connection box that is completed in a manner such that the insulating plate 5, which is fitted with the busbar 4b, the upper casing 2, etc. are successively attached to the wiring board 3 in this state, the insulator-coated portion of the wire trailer Ws and the edge of the busbar 4b may be caused to rub against each other by the vehicle's vibration. After all, the insulator-coated portion may break, possibly causing a short circuit between the conductor of the wire W and the busbar 4b.

This trouble occurs most easily if the peripheral wall of the lower casing 1 is warped inward. Since the lower casing 1 is generally formed of resin, its peripheral wall may be warped with high possibility. If the wiring board 3 is attached to the warped lower casing 1, the clearance between the peripheral edge of the board 3 and the inner surface of the peripheral wall of the casing 1 is reduced, so that the trailer Ws of the wire W easily interferes with the peripheral wall of the casing 1.

In order to avoid such an awkward situation, an assembler is expected to check the peripheral wall of the lower casing 1 to see if it is warped and to confirm that the wire trailer Ws is not projecting from the notch 3k at the end of each cycle of laying operation. After the wiring board 3 is attached to the lower casing 1, an extra operation is needed to see if the wire trailer Ws is suitably located in the notch 3k.

### SUMMARY OF THE INVENTION

An object of the present invention is to provide an electrical connection box in which an end portion of a wire never projects from a desired wiring path in a wiring board.

Another object of the invention is to provide an electrical connection box for which laying operation can be carried out without causing the leader of a wire from projecting from a desired wiring path in a wiring board.

Still another object of the invention is to provide an electrical connection box in which a wiring board can be attached to an upper or lower casing without allowing the trailer of a wire laid on the wiring board to hinder the attachment or be disengaged from the wiring board.

In order to achieve the above objects, an electrical connection box according to the present invention for carrying electrical components comprises first and second casings capable of being combined with each other and an electrically insulating wiring board located between these casings and having a wire laid in a desired shape thereon. The wiring board has a wiring path in a desired shape and a holding portion for holding the leader of the wire laid in the wiring path.

In the electrical connection box constructed in this manner, the wire leader holding portion is formed in a laying position for the wire leader on the wiring board. Therefore, the curly wire leader can be prevented from projecting from or being lifted out of the wiring path as the wire is laid by means of an automatic laying apparatus.

Preferably, the wiring path of the wiring board is formed of a laying groove, and the holding portion is formed of a holding recess, which is extended on both sides of the laying groove in the width direction thereof so that it is wider than the groove.

According to this preferred arrangement, the wire leader can be securely held in the holding portion even if it is bent on either side in the width direction of the laying groove.

In order to achieve the above objects, moreover, an electrical connection box according to the invention for carrying electrical components comprises first and second casings capable of being combined with each other and an electrically insulating wiring board located between these casings and having a wire laid in a desired shape thereon. The wiring board, first casing, and/or second casing is formed having a holding portion for holding the trailer of the wire and preventing interference between the wire trailer and the first or second casing adjoining the wire trailer.

Since the holding portion for holding the trailer of the wire is formed in a suitable position in the wiring board, first casing, and/or second casing, the wire trailer can be prevented from interfering with the first or second casing that adjoins the trailer. Thus, the assembly of the electrical connection box cannot be hindered by such interference. Further, there is no possibility of the wire trailer getting out of a proper laying position and interfering with a busbar or the like. Accordingly, the busbar and the wire trailer cannot be caused to rub against each other by vibration. In consequence, an insulator-coated portion of the wire can be securely prevented from breaking and causing a short circuit between a conductor of the wire and the busbar.

### BRIEF DESCRIPTION OF THE DRAWINGS

The above and other objects, features, and advantages of the invention will be more apparent from the ensuing detailed description taken in connection with the accompanying drawings, in which:

FIG. 1 is an exploded perspective view of an electrical connection box 10 according to one embodiment of the invention;

FIG. 2 is a detailed perspective view showing a part (portion A in FIG. 1) of a wiring board 13 of the electrical connection box 10 shown in FIG. 1;

FIG. 3 is a further detailed view showing the way a leader Ws of a wire W is held on the wiring board 13 of FIG. 2;

FIG. 4 is an exploded perspective view of an electrical connection box 20 according to another embodiment of the invention;

FIG. 5 is a detailed perspective view showing a part (portion B in FIG. 4) of a wiring board 23 shown in FIG. 4;

FIG. 6 is a partial plan view showing the way a leader Ws of a wire W is held in a holding recess 23h of the wiring board 23 and a lower casing 21 is attached to the board 23;

FIG. 7 is a partial plan view showing a modification of the arrangement shown in FIG. 6;

FIG. 8 is a partial plan view showing another modification of the arrangement shown in FIG. 6;

FIG. 9 is an exploded perspective view showing a conventional electrical connection box;

FIG. 10 is a detailed view showing the way a leader Ws of a wire W is held in a wiring board 3 of a conventional electrical connection box;

FIG. 11 is a detailed perspective view showing the way a trailer Ws of the wire W is laid in the conventional electrical connection box; and

FIG. 12 is a partial plan view showing the way the wire W is laid on the wiring board 3 of the conventional electrical connection box and a lower casing 1 is attached to the board 3.

### DETAILED DESCRIPTION OF THE PREFERRED EMBODIMENTS

The present invention will now be described in detail with reference to the accompanying drawings.

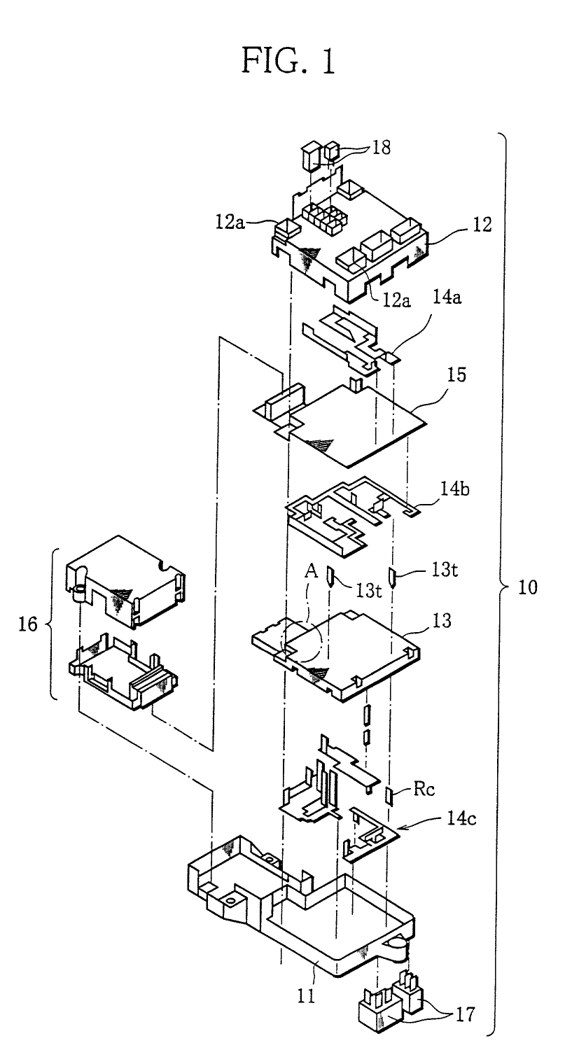

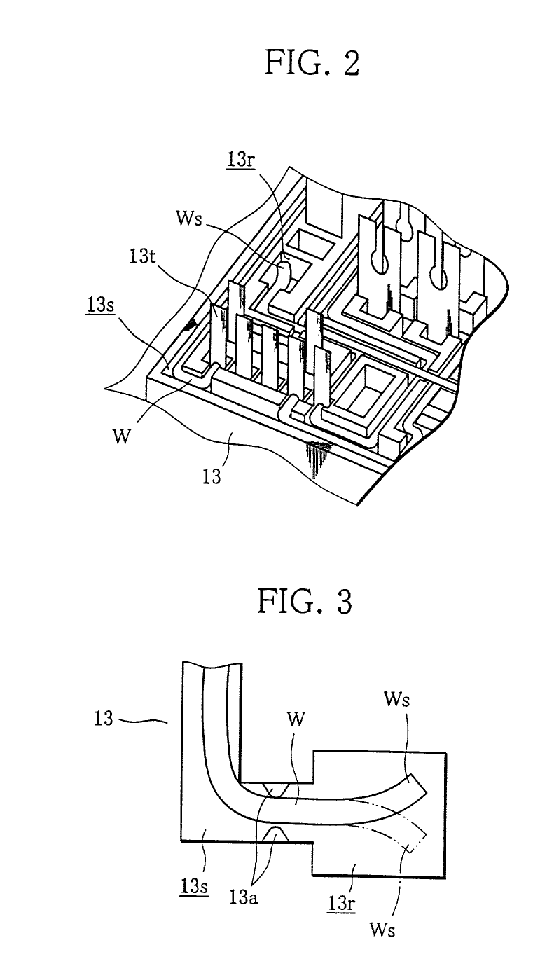

As shown in FIG. 1, an electrical connection box 10 according to one embodiment of the invention comprises a lower casing 11 fitted with relays 17, an upper casing 12 fitted with fuses 18 and formed with external connecting terminals 12a for connection with a wire harness, and an electrically insulating wiring board 13 located between the lower and upper casings 11 and 12 and having a wire W (shown in FIGS. 2 and 3 only) for low-current conduction thereon. The electrical connection box 10 further comprises busbars 14a, 14b and 14c interposed between the wiring board 13 and the upper casing 12 and between the wiring board 13 and the lower casing 11 and serving to conduct high current, an insulating plate 15 put on the wiring board 13, an electronic unit 16 attached to the lower casing 11, etc.

As shown in FIGS. 2 and 3, the wiring board 13 is formed with a laying groove 13s, which is a little wider than the wire W and extends lengthwise and crosswise. As shown in FIG. 2, the wire W is arranged with one stroke along a predetermined path of the laying groove 13s. In order to form a plurality of electrically independent circuits, the wire W is cut at given spots, and a plurality of pressure-welded terminals 13t are driven in given positions on the wire W. As shown in FIG. 1, the terminals 13t are connected electrically to electrical components, such as the relays 17, fuses 18, external connecting terminals 12a, etc., through a receptacle Rc. On the other hand, the busbars 14a, 14b and 14c serve to form a circuit for high-current conduction, and the insulating plate 15 is interposed between the busbars 14a and 14b. The insulating plate 15 is formed having insulating protrusions (not shown) in given positions on its surface that faces the wiring board 13. The insulating protrusions are fitted individually in the cut portions of the wire W that is laid on the wiring board 13, whereby insulation between the circuits formed by the wire W is secured.

As shown in FIGS. 2 and 3, a holding portion 13r is formed in that portion in the laying groove 13s of the wiring board 13 which has a wire leader Ws therein. The holding portion 13r is in the form of a rectangular recess that is wider than the laying groove 13s on either side. The holding portion 13r is wide and long enough to hold the wire leader Ws that is curly because it is cut or wound in a roll by means of an automatic laying apparatus (not shown). In the case where the wire W with a diameter of 1.5 mm and a projection length (outside the head of the automatic laying apparatus) of about 5 mm is laid in the laying groove 13s of 2.0-mm width, the holding portion 13r measures about 5.0 mm in width and about 7.0 mm in length. As shown in FIG. 3, on the other hand, wire retaining projections 13a are formed individually on the opposite sides of the inner wall of the laying groove 13s near the holding portion. Once the wire W is fitted in the laying groove 13s, therefore, it cannot easily slip out of the groove.

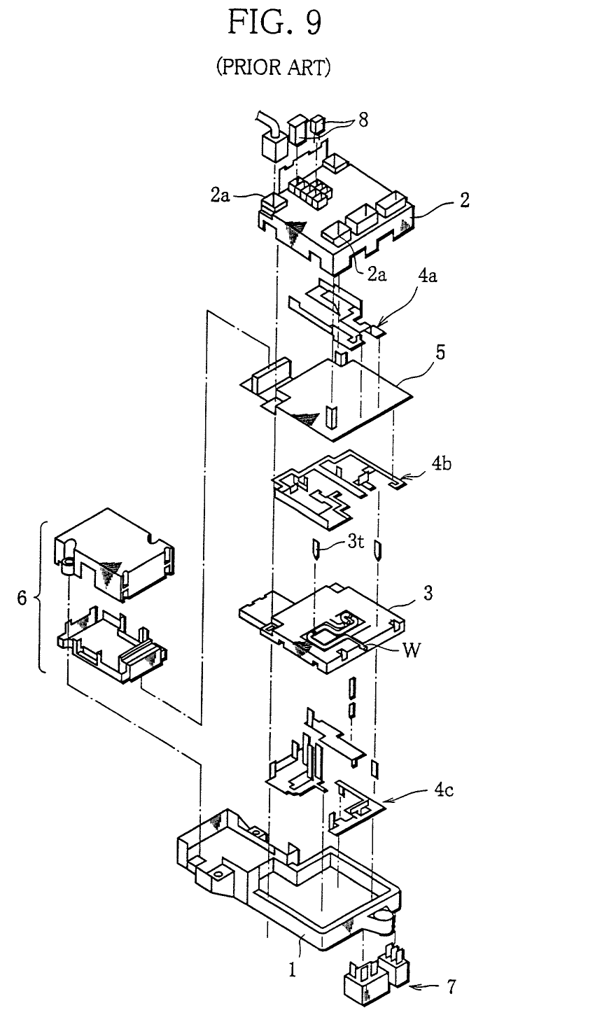

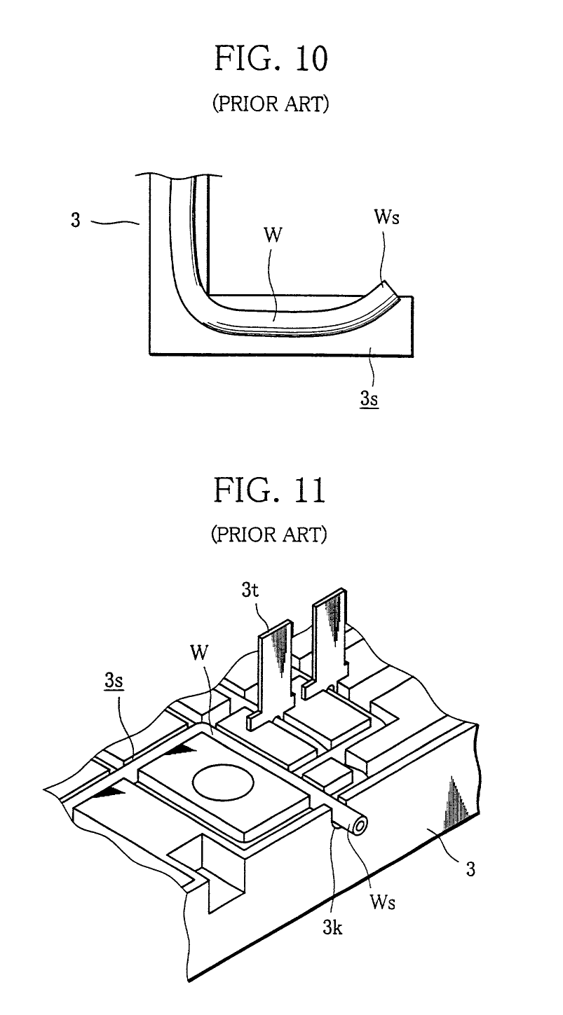

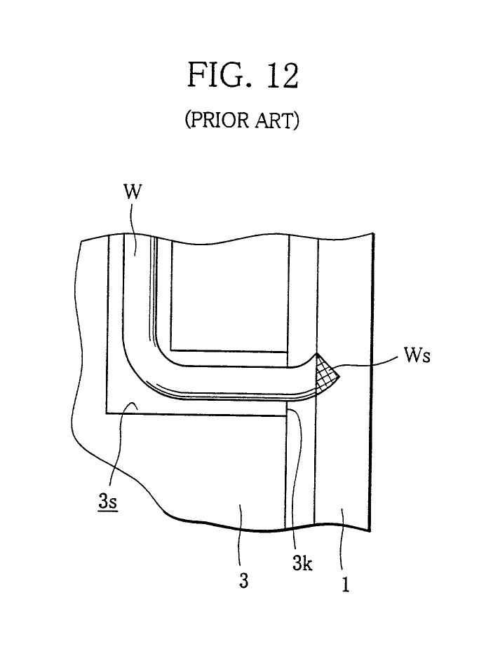

In the electrical connection box 10 constructed in this manner, the wire leader Ws, which extends from the head of the automatic laying apparatus to a cutter, is pushed into the laying groove 13s by means of a push pin (not shown) as the wire W is laid by means of the laying apparatus. If the leader Ws is bent in doing this, the bent portion can be held in the wide holding portion 13r. Unlike the conventional electrical connection box shown in FIG. 9, therefore, the connection box 10 can prevent the wire leader Ws from projecting from or being lifted out of the laying groove 13s. Accordingly, it is unnecessary, after laying operation, to see if the leader Ws projects from or is lifted out of the laying groove 13s, as shown in FIG. 10, or to push the leader Ws into the groove 13s. In consequence, the laying operation can be carried out efficiently.

Since the holding portion 13r is wider than the laying groove 13s on either side, moreover, the wire leader Ws can be securely held in the holding portion 13r if it is bent in any direction (e.g., in the direction indicated by full line or two-dot chain line in FIG. 3). Thus, the wire leader Ws can be securely held in the holding portion 13r without regard to the winding direction of the wire W to be laid and the direction of attachment of the cutter that is used to cut the wire W after the laying operation. In consequence, the laying operation can be carried out efficiently.

If the busbar 14b, insulating plate 15, and lower and upper casings 11 and 12 are joined together with the wire leader Ws projecting from or lifted out of the laying groove 13s, the leader Ws is left in contact with the busbar 14b. If a conductor exposed through the leader Ws touches the busbar 14b or if the use of the electrical connection box 10 is prolonged, the leader Ws is caused to rub against the busbar 14b by a vehicle's vibration, so that its insulator-coated portion may break, possibly causing a short circuit. However, such trouble can be securely avoided if the wire leader Ws is steadily held in the holding portion 13r, as mentioned before.

Alternatively, the holding portion may be formed so that it is wider than the laying groove only on one side. If the depth of the laying groove is not much greater than the diameter of the wire, moreover, the holding portion may be made deeper than the laying groove.

The plane shape of the holding portion need not be rectangular, and may alternatively be circular or elliptic only if the holding portion can hold the wire leader Ws entire.

If the wiring path is not a laying groove, that is, if it is formed of protrusions that are opposed to one another to hold the wire between them and arranged at given intervals such that the wire can enjoy a desired configuration, a space that is wide enough to hold the bent wire leader may be defined in the position for the location of the wire leader.

Both the upper and lower casings need not be fitted with the electrical components, that is, one of the casings should only be fitted with the electrical parts. Further, the electrical components that are mounted in the electrical connection box are not limited to the relays, fuses, and external connecting terminals, and may include capacitors, diodes, etc., for example.

The following is a description of an electrical connection box according to another embodiment of the present invention.

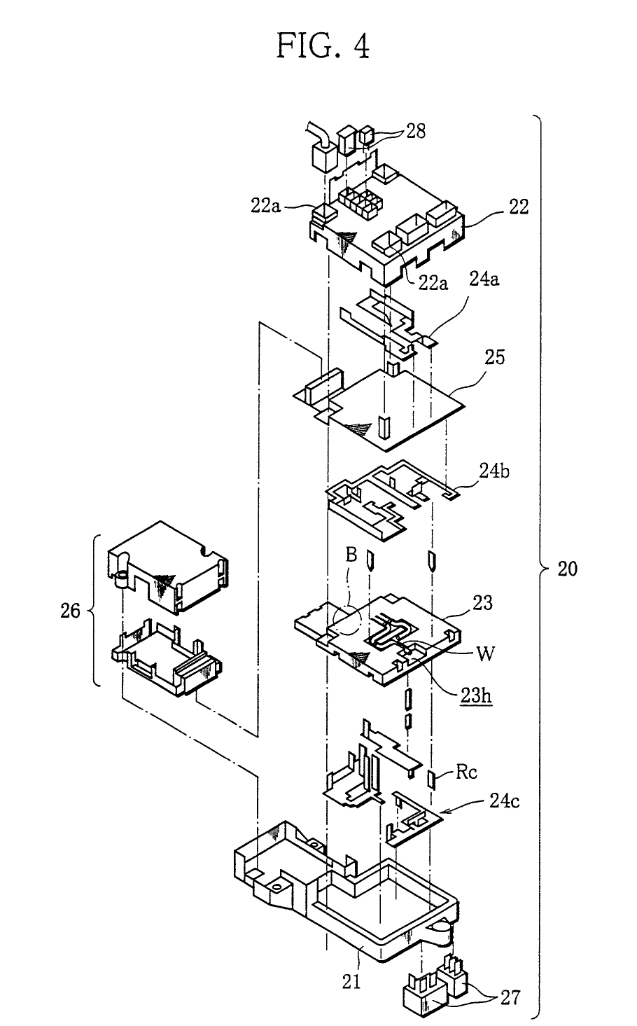

As shown in FIG. 4, an electrical connection box 20 according to the second embodiment of the invention comprises a lower casing 21 fitted with relays 27, an upper casing 22 fitted with fuses 28 and formed with external connecting terminals 22a for connection with a wire harness, and an electrically insulating wiring board 23 located between the lower and upper casings 21 and 22 and having a wire W for low-current conduction thereon. The electrical connection box 20 further comprises busbars 24a, 24b and 24c interposed between the wiring board 23 and the upper casing 22 and between the wiring board 23 and the lower casing 21 and serving to conduct high current, an insulating plate 25 put on the wiring board 23, an electronic unit 26 attached to the lower casing 21, etc.

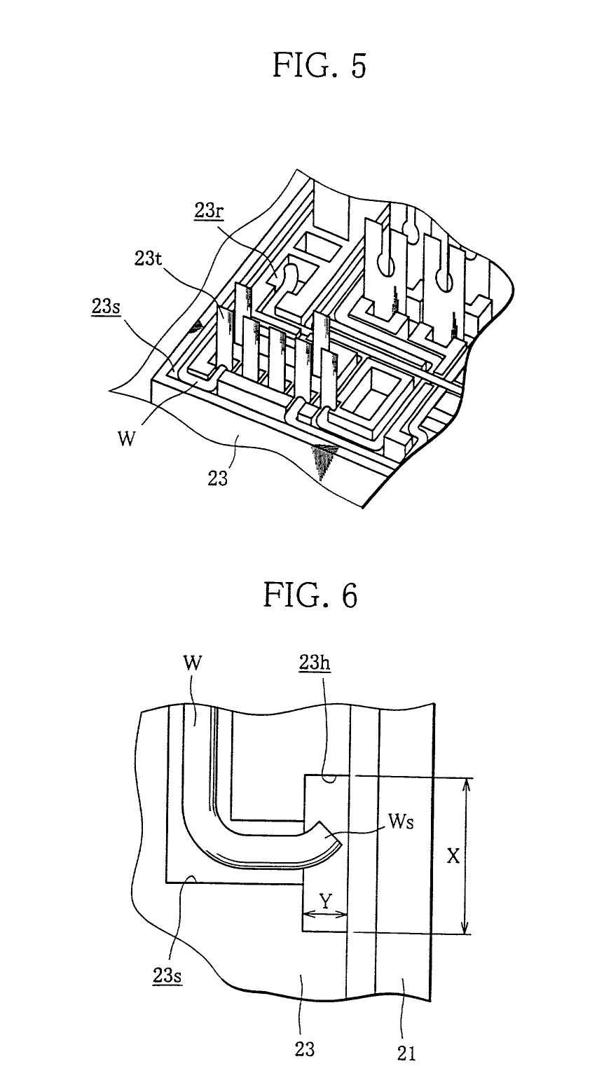

As shown in FIG. 5, the wiring board 23 is formed with a laying groove 23s, which is a little wider than the wire W and extends lengthwise and crosswise. Besides, the wire W is arranged with one stroke along a leader holding portion 23r and a predetermined path of the laying groove 23s. In order to form a plurality of independent circuits, the wire W is cut at given spots, and a plurality of pressure-welded terminals 23t are driven in given positions on the wire W. As shown in FIG. 4, the terminals 23t are connected electrically to electrical components, such as the relays 27, fuses 28, external connecting terminals 22a, etc., through a receptacle Rc. On the other hand, the busbars 24a, 24b and 24c serve to form a circuit for high-current conduction, and the insulating plate 25 is interposed between the busbars 24a and 24b. The insulating plate 25 is formed having insulating protrusions (not shown) in given positions on its surface that faces the wiring board 23. The insulating protrusions are fitted individually in the cut portions of the wire W that is laid on the wiring board 23, whereby insulation between the circuits formed by the wire W is secured.

As shown in FIGS. 4 and 6, a holding recess 23h for holding a wire trailer Ws is formed in a given position in a peripheral edge portion of the wiring board 23. The recess 23h has a width X great enough to receive a cutter for cutting the wire W and a horizontal depth Y such that the trailer Ws cannot project from the outer peripheral surface of the wiring board 23 when the wire W is cut by means of the cutter. The holding recess 23h spreads crosswise on either side of the laying groove 23s so that it can securely hold the wire trailer Ws even though the trailer Ws is curly, as shown in FIG. 6.

According to the electrical connection box 20 constructed in this manner, the wire W can be cut by means of the cutter with its distal end in the holding recess 23h after the wire W is wiring laid by means of the automatic laying apparatus. In consequence, the wire trailer Ws can be prevented from unduly projecting from the outer peripheral edge of the wiring board 23. Although the wiring board 23 is attached to the lower casing 21 after the laying operation, therefore, the trailer Ws and the peripheral wall of the lower casing 21 are distant enough not to interfere with each other, as shown in FIG. 6. If the inner peripheral wall of the lower casing 21 is warped inward as it is molded, moreover, it never interferes with the wire trailer Ws. Thus, the wiring board 23 can be securely prevented from failing to be attached to the lower casing 21 or from separating from the trailer Ws when it is attached to the lower casing 21.

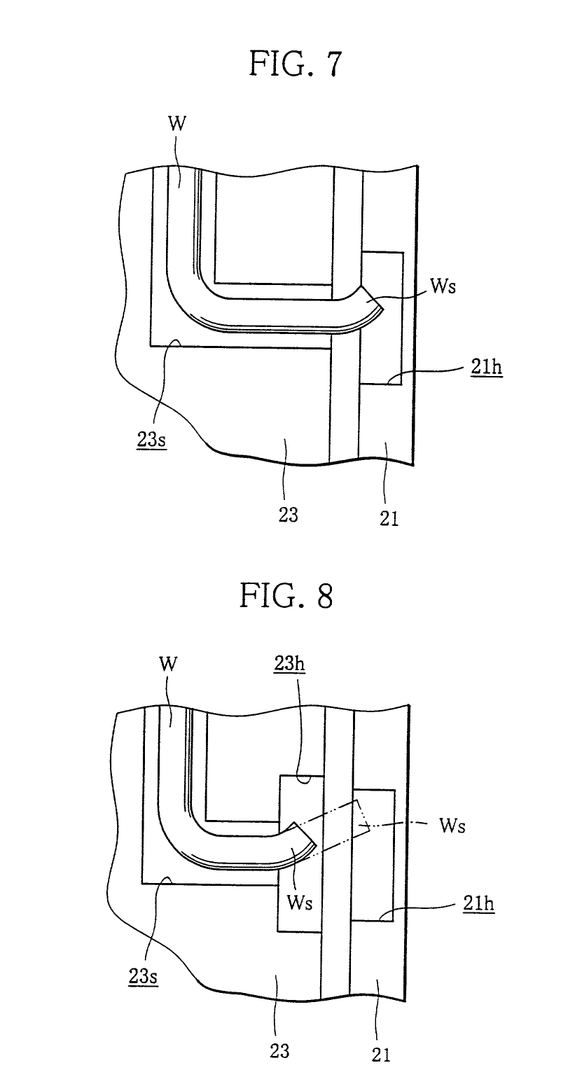

As shown in FIG. 7, a holding recess 21h may alternatively be formed in the inner side face of the peripheral wall of the lower casing 21. The recess 21h has a width such that it never interferes with the wire trailer Ws that projects from the wiring board 23. The recess 23h has a depth such that the trailer Ws never interferes with the inner peripheral wall of the lower casing 21 when the wiring board 23 is attached to the casing 21. With the holding recess 21h formed in the lower casing 21, the wire W need not be cut in the holding recess 23h of the wiring board 23 according to the embodiment shown in FIG. 6, so that a relatively large-sized cutter can be used for the wire cutting operation.

As shown in FIG. 8, moreover, the lower casing 21 and the wiring board 23 may be provided with the holding recesses 21h and 23h, respectively. The recesses 21h and 23h form a substantial space wide enough to prevent interference between the lower casing 21 and the wire W even if the wire trailer Ws projects long, as indicated by two-dot chain line in FIG. 8.

In the case of an electrical connection box designed so that an upper casing fitted with a wiring board is attached to a lower casing, unlike the foregoing embodiments, it is advisable to form a holding recess in the upper casing in place of the lower casing. Thus, the trailer of a wire can be prevented from interfering with the peripheral wall of the upper casing.

Although the specific embodiments of the present invention have been shown and described herein, it is to understood that the invention is not limited to the embodiments described above, and that various changes and modifications may be effected therein by one skilled in the art without departing from the scope or spirit of the invention.

What is claimed is:

1. An electrical connection box for carrying electrical components, comprising:
first and second casings capable of being combined with each other; and
an electrically insulating wiring board located between the first and second casings and having a wire laid in a desired shape thereon,
the wiring board having a wiring path in a desired shape and a holding portion for holding the leader of the wire laid in the wiring path.

2. An electrical connection box for carrying electrical components, comprising:
first and second casings capable of being combined with each other; and
an electrically insulating wiring board located between the first and second casings and having a wire laid in a desired shape thereon,
the wiring board, first casing, and/or second casing being formed having a holding portion for holding the trailer of the wire and preventing interference between the wire trailer and the first or second casing adjoining the wire trailer.

3. The electrical connection box according to claim 1, wherein said holding portion is wider than the wiring path.

4. The electrical connection box according to claim 1, wherein said wiring path of the wiring board is formed of a laying groove, and said holding portion is formed of a holding recess wider than the laying groove.

5. The electrical connection box according to claim 4, wherein said holding recess is extended on both sides of the laying groove in the width direction thereof.

6. The electrical connection box according to claim 2, further comprising a holding recess located in that position on the peripheral edge portion of the wiring board which corresponds to the trailer of the wire and capable of holding the wire trailer.

7. The electrical connection box according to claim 2, further comprising a holding recess located in that position in the inner wall of the first casing which corresponds to the trailer of the wire and capable of holding the wire trailer.

8. The electrical connection box according to claim 2, further comprising a holding recess located in that position in the inner wall of the second casing which corresponds to the trailer of the wire and capable of holding the wire trailer.
